(19) United States
(12) Patent Application Publication
(10) Pub. No.: US 2026/0271285 A1
(43) Pub. Date: Sep. 10, 2026

(54) SEMICONDUCTOR DEVICE

(71) Applicant: Kioxia Corporation, Tokyo (JP)

(72) Inventor: Kazunari TOYONAGA, Yokkaichi Mie (JP)

(21) Appl. No.: 19/322,417

(22) Filed: Sep. 8, 2025

(30) Foreign Application Priority Data
Mar. 10, 2025 (JP) 2025-037601

(51) Int. Cl. H10B 41/35; H10B 41/10; H10B 41/41; H10B 43/10; H10B 43/35; H10B 43/40

(52) U.S. Cl. CPC H10B 41/35; H10B 41/41; H10B 43/35; H10B 43/40; H10B 41/10; H10B 43/10

(57) ABSTRACT

According to one embodiment, the same transistor structure can be used for different voltage operations. A semiconductor device includes a first transistor in which a first gate insulation layer, a first gate electrode, a second gate insulation layer, and a second gate electrode are stacked in this order. A first contact is connected to the first gate electrode, and a second contact is connected to the second gate electrode.

### CROSS-REFERENCE TO RELATED APPLICATIONS

This application is based upon and claims the benefit of priority from Japanese Patent Application No. 2025-037601, filed Mar. 10, 2025, the entire contents of which are incorporated herein by reference.

### FIELD

Embodiments described herein relate generally to a semiconductor device.

### BACKGROUND

There are semiconductor devices in which a plurality of transistors are provided on a semiconductor substrate. In such semiconductor devices, there may be cases in which the properties of each transistor, such as a transfer voltage, may vary according to the processing details used in device fabrication.

### BRIEF DESCRIPTION OF THE DRAWINGS

FIG. 1 is a block diagram of a semiconductor device according to an embodiment.

FIG. 2 is an equivalent circuit diagram of a memory cell array of a semiconductor device according to an embodiment.

FIG. 3 is a circuit diagram of a sense amplifier circuit and latch circuits of a semiconductor device according to an embodiment.

FIG. 4 is a circuit diagram of a row decoder of a semiconductor device according to an embodiment.

FIG. 5 is a cross-sectional view of a semiconductor device according to an embodiment.

FIG. 6 is a diagram showing an example of a physical configuration of a row decoder of a semiconductor device according to an embodiment.

FIG. 7 is a schematic view for illustrating aspects of electrical operations of a transistor according to an embodiment.

FIG. 8 illustrates aspects of a method of manufacturing a semiconductor device according to an embodiment.

FIG. 9 illustrates aspects of a method of manufacturing a semiconductor device according to an embodiment.

FIG. 10 is a top plan view of transistors included in a row decoder of a semiconductor device according to modification 1 of an embodiment.

FIG. 11 is a top plan view of transistors included in a row decoder of a semiconductor device according to modification 2 of an embodiment.

FIG. 12 is an equivalent circuit diagram of bit line selection circuits in which transistors according to modification 3 of an embodiment are incorporated.

FIG. 13 is a diagram showing an example of a physical configuration of transistors included in a bit line selection circuit of a semiconductor device according to modification 3 of the embodiment.

### DETAILED DESCRIPTION

It is an object of one embodiment to provide a semiconductor device in which the same transistor structure can be used with various voltage operations as appropriate to device operations.

In general, according to one embodiment, a semiconductor device includes a first transistor that has a first gate insulation layer, a first gate electrode, a second gate insulation layer, and a second gate electrode, which are stacked in this order one upon the other. A first contact is connected to the first gate electrode, and second contact is connected to the second gate electrode.

Hereinafter, certain example embodiments of the present disclosure will be described with reference to drawings. The present disclosure is not limited by the example embodiments described below. The embodiments may be varied or altered in manners readily apparent to those skilled in the art.

### Circuit Configuration of Semiconductor Device

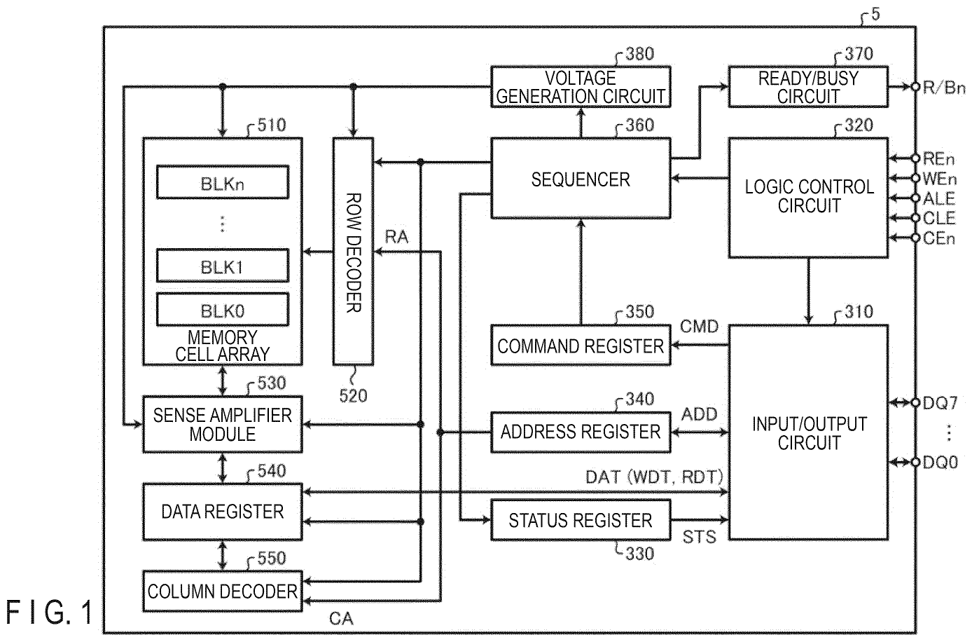

First, an example of the circuit configuration of a semiconductor device 1 of an embodiment will be described with reference to FIG. 1 to FIG. 4.

### Overall Configuration of Semiconductor Device

FIG. 1 is a block diagram of the semiconductor device 1. As depicted in FIG. 1, the semiconductor device 1 includes an input/output circuit 310, a logic control circuit 320, a status register 330, an address register 340, a command register 350, a sequencer 360, a ready/busy circuit 370, a voltage generation circuit 380, a memory cell array 510, a row decoder 520, a sense amplifier module 530, a data register 540, and a column decoder 550.

The input/output circuit 310 handles input/output of signals DQ from/to an external device, such as a memory controller or the like, that controls operations of the semiconductor device 1. The input/output circuit 310 includes an input circuit and an output circuit, which are not separately depicted in the drawing.

The input circuit sends data DAT (such as write data WDT) received from an external device to the data register 540, an address ADD to the address register 340, and a command CMD to the command register 350.

The output circuit sends, to the external device, status information STS received from the status register 330, data DAT (such as read data RDT) received from the data register 540, and an address ADD received from the address register 340.

The logic control circuit 320 receives, from the external device, signals such as a chip enable signal CEn, a command latch enable signal CLE, an address latch enable signal ALE, a write enable signal WEn, and a read enable signal REn. In addition, the logic control circuit 320 controls the input/output circuit 310 and the sequencer 360 in response to the received signals.

The status register 330 temporarily holds status information STS during a data write operation, a data read operation, or a data erase operation, and notifies the external device of whether the operation has ended normally.

The address register 340 temporarily holds the address ADD received from the external device via the input/output circuit 310. In addition, the address register 340 transfers a row address RA to the row decoder 520 and a column address CA to the column decoder 550.

The command register 350 temporarily stores the command CMD, received from the external device via the input/output circuit 310, and transfers the command CMD to the sequencer 360.

The sequencer 360 controls the overall operation of the semiconductor device 1. More specifically, in response to the command CMD in the command register 350, the sequencer 360 controls the status register 330, the ready/busy circuit 370, the voltage generation circuit 380, the row decoder 520, the sense amplifier module 530, the data register 540, the column decoder 550, and the like to perform a write operation, a read operation, an erase operation, or the like.

The ready/busy circuit 370 transmits a ready/busy signal R/Bn to the external device according to the current operation state of the sequencer 360.

In response to the control by the sequencer 360, the voltage generation circuit 380 generates voltages necessary for the write operation, the read operation, or the erase operation, and supplies a generated voltage to the memory cell array 510, the row decoder 520, and the sense amplifier module 530 as appropriate. The row decoder 520 and the sense amplifier module 530 apply the voltage supplied from the voltage generation circuit 380 to memory cells in the memory cell array 510.

The memory cell array 510 includes a plurality of blocks BLK (BLK0 to BLKn), where “n” is an integer of two or more. Each block BLK is a collection of memory cells associated with bit lines and word lines and is a unit by which data is erased, for example. Each memory cell is constituted as a transistor, for example, and holds data in a nonvolatile manner.

The semiconductor device 1 includes nonvolatile memory cells, thus, in some examples, may be a NAND-type nonvolatile memory.

The row decoder 520 decodes the row address RA. In addition, the row decoder 520 selects a block BLK based on the decode result. The row decoder 520 applies a necessary voltage to the block BLK.

In the read operation, the sense amplifier module 530 senses data that is read from the memory cell array 510. In addition, the sense amplifier module 530 transmits the read data RDT to the data register 540. In the write operation, the sense amplifier module 530 transmits the write data WDT to the memory cell array 510 for storage therein.

The data register 540 includes a plurality of latch circuits. The latch circuits hold the write data WDT and the read data RDT. In the write operation, the data register 540 temporarily holds the write data WDT received from the input/output circuit 310 and transmits the write data WDT to the sense amplifier module 530. In the read operation, the data register 540 temporarily holds the read data RDT received from the sense amplifier module 530 and transmits the read data RDT to the input/output circuit 310.

In the write operation, the read operation, and the erase operation, the column decoder 550 decodes the column address CA and selects a latch circuit in the data register 540 according to the decode result.

Circuit groups disposed outside of the memory cell array 510 are also referred to as “peripheral circuits”. These peripheral circuits include at least the row decoder 520, the sense amplifier module 530, the data register 540, and the column decoder 550. The peripheral circuits may include the status register 330, the address register 340, the command register 350, and the sequencer 360, and may further include the input/output circuit 310, the logic control circuit 320, the ready/busy circuit 370, and the voltage generation circuit 380.

As described above, the semiconductor device 1 includes the memory cell array 510 and its peripheral circuits and the memory cells in the memory cell array 510. The peripheral circuits perform operations on the plurality of memory cells.

### Circuit Configuration of Memory Cell Array

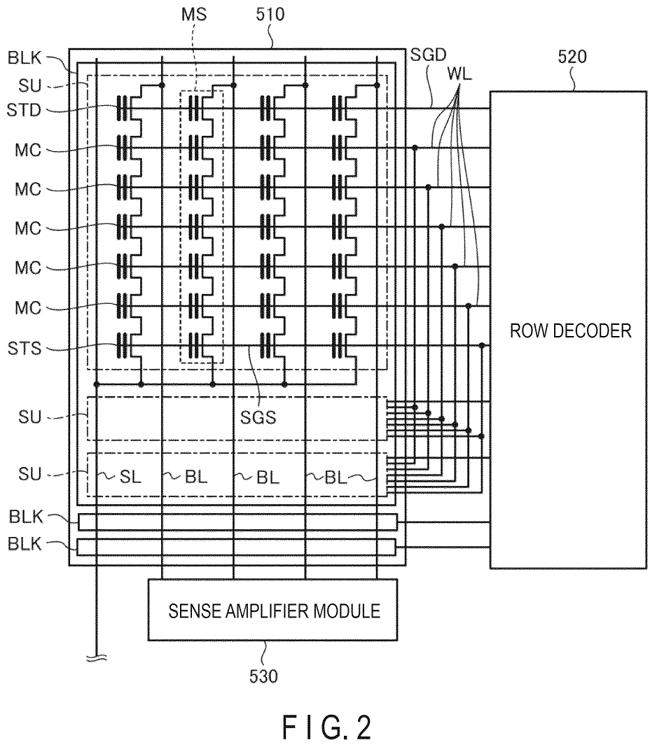

FIG. 2 is an equivalent circuit diagram showing an example of the configuration of the memory cell array 510 of the semiconductor device 1 according to an embodiment.

As described above, the memory cell array 510 includes a plurality of blocks BLK. Each of the blocks BLK includes a plurality of string units SU. Each of the string units SU includes a plurality of memory strings MS. One end of each memory string MS is connected to a peripheral circuit, such as the sense amplifier module 530, via a bit line BL. The other end of each memory string MS is connected to a peripheral circuit via a common source line SL.

Each memory string MS includes a drain select transistor STD, which is connected in series between the bit line BL and the source line SL, a plurality of memory cells MC, and a source select transistor STS. Hereinafter, the drain select transistor STD and the source select transistor STS may be more simply referred to as “select transistors (STD, STS)”.

Each memory cell MC is, for example, a field effect transistor (FET) in which a gate insulation layer includes a charge storage layer. The threshold voltage of the memory cell MC changes according to the amount of charge in the charge storage layer. By providing one or more threshold voltage levels, a memory cell MC may be capable of storing data of one bit or a plurality of bits. Different word lines WL are connected to the gate electrodes of the different memory cells MC in the same memory string MS. These word lines WL are shared by all of the memory strings MS in the same block BLK.

The select transistors (STD, STS) are field effect transistors, for example. Select gate lines (SGD, SGS) are connected to the gate electrodes of the select transistors (STD, STS). A drain select line SGD (connected to the drain select transistors STD) is provided for each string unit SU and is connected to all of the memory strings MS in the same string unit SU in a common manner. A source select line SGS connected to the source select transistors STS of all of the memory strings MS in the same block BLK in a common manner.

One end of each of the word lines WL and the select gate lines (SGD, SGS) is connected to a peripheral circuit, such as the row decoder 520.

### Circuit Configuration of Sense Amplifier Module

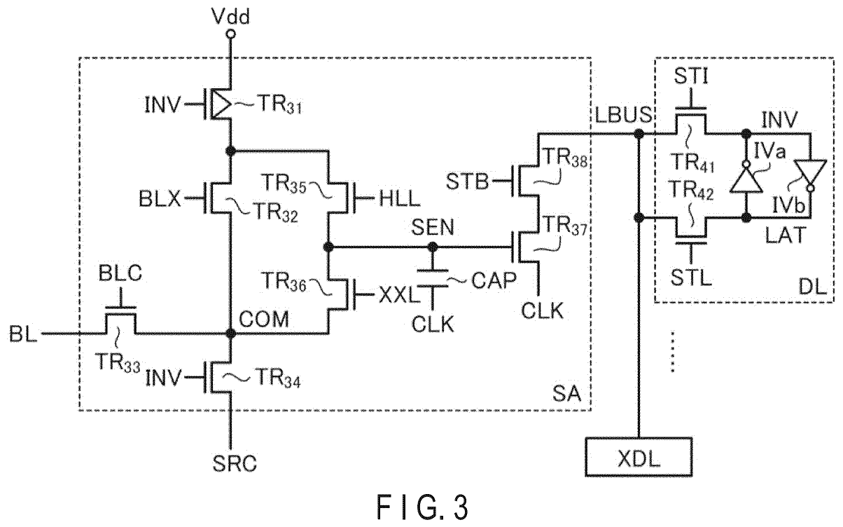

FIG. 3 is a circuit diagram showing an example of the configurations of a sense amplifier circuit SA and latch circuits DL, XDL of the semiconductor device 1 according to the embodiment.

The sense amplifier module 530 includes a plurality of sense amplifier circuits SA, each of which is provided for a different bit line BL. In the read operation, the individual sense amplifier circuit SA senses data read via the corresponding bit line BL and determines whether the read data is “0” or “1”.

The data register 540 also includes a plurality of latch circuits DL and a plurality of latch circuits XDL that correspond to the plurality of sense amplifier circuits SA. A latch circuit XDL is provided for each bit line BL. In contrast, a plurality of latch circuits DL are provided for a corresponding sense amplifier circuit SA. In this case, the number of latch circuits DL is set based on the number of bits of data that each memory cell MC can hold. The latch circuits DL, XDL temporarily hold data relating to the corresponding bit lines BL.

FIG. 3 shows one sense amplifier circuit SA in the sense amplifier module 530, and one latch circuit DL and one latch circuit XDL in the data register 540. A plurality of control signals supplied to the sense amplifier circuits SA and the like are controlled by the sequencer 360.

As shown in FIG. 3, each sense amplifier circuit SA includes transistors TR₃₁ to TR₃₈ and a capacitor CAP. In the drawing, the transistor TR₃₁ is a low breakdown voltage P-channel metal-oxide-semiconductor (MOS) transistor. The transistors TR₃₂ to TR₃₈ are low breakdown voltage N-channel MOS transistors.

These low breakdown voltage CMOS transistors are transistors to which a relatively low voltage is applied, and such low breakdown voltage CMOS transistors are also referred to as “low voltage (LV) MOS transistors” or sometimes “very low voltage (VLV) MOS transistors”.

One end of the transistor TR₃₁ is connected to a power supply line to which a power supply voltage Vdd is supplied, and the gate electrode of the transistor TR₃₁ is connected to a node INV. One end of the transistor TR₃₂ is connected to the other end of the transistor TR₃₁, the other end of the transistor TR₃₂ is connected to a node COM, and a control signal BLX is inputted into the gate electrode of the transistor TR₃₂. One end of the transistor TR₃₃ is connected to the node COM, the other end of the transistor TR₃₃ is connected to the corresponding bit line BL, and a control signal BLC is inputted into the gate electrode of the transistor TR₃₃.

One end of the transistor TR₃₄ is connected to the node COM, the other end of the transistor TR₃₄ is connected to a node SRC, and the gate electrode of the transistor TR₃₄ is connected to a node INV.

One end of the transistor TR₃₅ is connected to the other end of the transistor TR₃₁, the other end of the transistor TR₃₅ is connected to a node SEN, and a control signal HLL is inputted into the gate electrode of the transistor TR₃₅. One end of the transistor TR₃₆ is connected to the node SEN, the other end of the transistor TR₃₆ is connected to the node COM, and a control signal XXL is inputted into the gate electrode of the transistor TR₃₆.

A clock CLK (clock signal) is inputted into one end of the transistor TR₃₇, and the gate electrode of the transistor TR₃₇ is connected to the node SEN. One end of the transistor TR₃₈ is connected to the other end of the transistor TR₃₇, the other end of the transistor TR₃₈ is connected to a bus LBUS, and a control signal STB is inputted into the gate electrode of the transistor TR₃₈. One end of the capacitor CAP is connected to the node SEN, and a clock CLK is inputted into the other end of the capacitor CAP.

The latch circuit DL includes inverters IVa, IVb, and transistors TR₄₁, TR₄₂. In the drawing, the transistors TR₄₁, TR₄₂ are low breakdown voltage N-channel MOS transistors.

Although just one latch circuit DL is shown in detail in FIG. 3, other latch circuits DL also have substantially the same configuration.

The input terminal of the inverter Iva is connected to a node LAT, and the output terminal of the inverter Iva is connected to a node INV. The input terminal of the inverter IVb is connected to the node INV, and the output terminal of the inverter IVb is connected to the node LAT.

One end of the transistor TR₄₁ is connected to the node INV, the other end of the transistor TR₄₁ is connected to the bus LBUS, and a control signal STI is inputted into the gate electrode of the transistor TR₄₁. One end of the transistor TR₄₂ is connected to the node LAT, the other end of the transistor TR₄₂ is connected to the bus LBUS, and a control signal STL is inputted into the gate electrode of the transistor TR₄₂.

The latch circuit XDL has substantially the same configuration as a latch circuit DL, for example, and is connected to the bus LBUS in such a way as to be capable of transmitting/receiving data to/from the sense amplifier circuit SA and the latch circuit DL. The latch circuit XDL is connected to the input/output circuit 310 and is used for inputting/outputting data between the sense amplifier circuit SA and the input/output circuit 310.

The latch circuit XDL may also be used for a cache operation of the semiconductor device 1. That is, even in the case in which all of the latch circuits DL that correspond to the sense amplifier circuits SA are in use, when the latch circuits XDL are available, the semiconductor device 1 can still receive/store data from an external device.

As described above, each of the sense amplifier circuit SA and the latch circuits DL, XDL in the peripheral circuits includes a plurality of transistors TR.

Next, the operation of a sense amplifier circuit SA having the above-mentioned configuration will be described.

When data is written into a memory cell MC, for a case in which charge is injected into the memory cell MC to raise its threshold, an “H” level (data “1”) is stored in the node INV of the latch circuit DL. Consequently, the transistor TR₃₄ is turned on, and the bit line BL is set to 0 V.

When data is written into the memory cell MC, for a case in which charge is not injected into a memory cell MC, and its threshold is not changed, an “L” level (data “0”) is stored in the node INV of the latch circuit DL. Consequently, the transistor TR₃₁ is turned on, and a predetermined positive voltage is applied to the bit line BL.

In reading data, the node INV is set to an “L” level, and the transistor TR₃₁ is turned on. In addition, the bit line BL is pre-charged by the transistor TR₃₁ via the transistors TR₄₁, TR₄₂. The transistor TR₃₅ is also turned on, and the node SEN is charged up to a predetermined potential.

Thereafter, the transistor TR₃₅ is turned off, and the signal XXL is set to an “H” level, so that the transistor TR₃₆ is turned on. Consequently, when the corresponding memory cell MC is in an on state, the potential of the node SEN is lowered, and the transistor TR₃₇ is turned off. In contrast, when the corresponding memory cell MC is in an off state, the potential of the node SEN maintains an “H” level, and the transistor TR₃₇ is turned on.

In addition, the transistor TR₃₈ is turned on in response to the signal STB, a potential that corresponds to the turning on/off of the transistor TR₃₇ is read by the bus LBUS, and the potential is held by the latch circuit DL.

The circuit configurations of the sense amplifier circuit SA and the latch circuits DL, XDL shown in FIG. 3 are merely examples, and the sense amplifier circuit SA and the latch circuits DL, XDL may have various configurations other than the above-mentioned configurations. Therefore, the number and kinds of the transistors TR included in each of the sense amplifier circuit SA and the latch circuits DL, XDL may vary. For example, the sense amplifier circuit SA and the latch circuits DL, XDL may be configured to include high breakdown voltage P-channel MOS transistors, high breakdown voltage N-channel MOS transistors, or the like.

### Circuit Configuration of Row Decoder

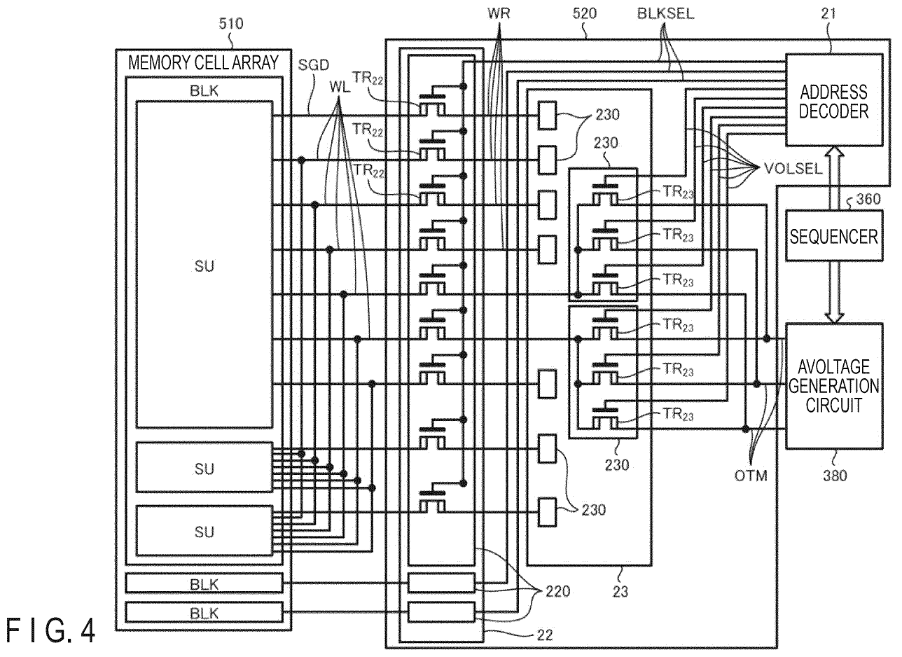

FIG. 4 is a circuit diagram showing an example of the configuration of the row decoder 520 of the semiconductor device 1 according to an embodiment.

As shown in FIG. 4, the row decoder 520 includes an address decoder 21, a block selection circuit 22, and a voltage selection circuit 23.

The address decoder 21 includes a plurality of block select lines BLKSEL and a plurality of voltage select lines VOLSEL.

In response to a control signal from the sequencer 360, the address decoder 21 refers to address data in the address register 340 included in the corresponding peripheral circuits.

The address decoder 21 also decodes the referred address data. Thereafter, the address decoder 21 turns on transistors TR₂₂ and transistors TR₂₃ that correspond to the address data, and turns off the non-corresponding other transistors TR₂₂ and transistors TR₂₃. The transistors TR₂₂ are transistors included in a block selection circuit 22, and the transistors TR₂₃ are transistors included in a voltage selection circuit 23.

The address decoder 21 sets the voltage of the block select lines BLKSEL and the voltage select lines VOLSEL that correspond to the address data to an “H” state, and sets the voltage of other (non-selected/non-addressed) block select lines BLKSEL and select lines VOLSEL to an “L” state. Depending on whether N-channel type transistors or P-channel type transistors are used for the block selection circuit 22 and the voltage selection circuit 23, the voltage applied to these lines may be inverted. The above-mentioned voltage is an example for the case in which the transistors are N-channel type transistors.

In the example shown in FIG. 4, the address decoder 21 is provided with block select lines BLKSEL, one of which is provided for each block BLK in the memory cell array 510. However, this configuration may be suitably changed. For example, one block select line BLKSEL may be provided for two or more blocks BLK.

The block selection circuit 22 includes a plurality of block selection units 220, each of which corresponds to a block BLK of the memory cell array 510. Each of the block selection units 220 includes a plurality of transistors TR₂₂ that correspond to the word lines WL and the select gate lines (SGD, SGS).

Each transistor TR₂₂ is a high breakdown voltage N-channel MOS transistor and serves as a block driving transistor. The drain electrode of each transistor TR₂₂ is electrically connected to the corresponding word line WL or the corresponding select gate line (SGD, SGS). The source electrode of each transistor TR₂₂ is electrically connected to a voltage output terminal OTM via a wiring WR and the voltage selection circuit 23. The gate electrodes of the transistors TR₂₂ are connected to the corresponding block select line BLKSEL in a common manner.

In this configuration, the transistor TR₂₂ may also be referred to as a word line switch or the like since it can be used to select an individual word line WL or the like.

The block selection circuit 22 further includes a plurality of transistors not specifically depicted in FIG. 4. These other transistors are high breakdown voltage CMOS transistors connected between the select gate line (SGD, SGS) and a ground voltage supply terminal. These transistors cause the select gate lines (SGD, SGS) in a non-selected block BLK to be connected to the ground voltage supply terminal. The word lines WL in the non-selected block BLK are brought into a floating state.

The voltage selection circuit 23 includes a plurality of voltage selection units 230 that correspond to the word lines WL and the select gate lines (SGD, SGS). Each of these voltage selection units 230 includes a plurality of transistors TR₂₃.

Each transistor TR₂₃ is a high breakdown voltage N-channel MOS transistor and serves as a voltage select transistor. The drain terminal of each transistor TR₂₃ is electrically connected to the corresponding word line WL or the corresponding select gate line (SGD, SGS) via the wiring WR and the block selection circuit 22. The source terminal of each transistor TR₂₃ is electrically connected to the corresponding voltage output terminal OTM. The gate electrode of each transistor TR₂₃ is connected to the corresponding voltage select line VOLSEL.

The high breakdown voltage CMOS transistors, including the high breakdown voltage P-channel MOS transistor and high breakdown voltage N-channel MOS transistor, are transistors to which a relatively high voltage can be applied. Such high breakdown voltage CMOS transistors are also referred to as “high voltage (HV) MOS transistors”.

As described above, the row decoder 520 includes a plurality of transistors TR₂₂, TR₂₃. However, the circuit configuration of the row decoder 520 shown in FIG. 4 is merely an example, and the number of the transistors TR₂₂, TR₂₃ and types of transistors incorporated, or the like in the row decoder 520 may vary.

### Physical Configuration of Semiconductor Device

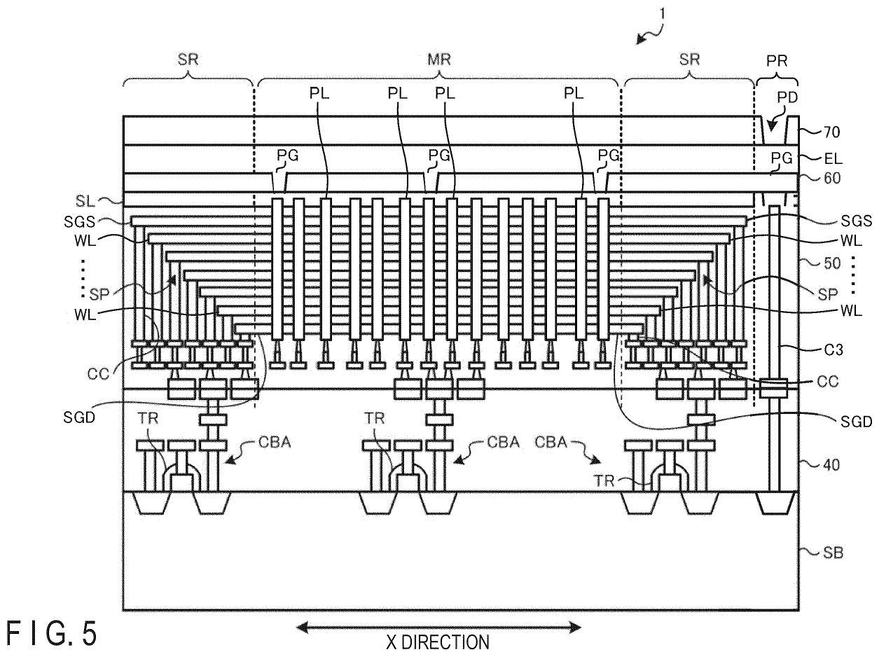

Next, an example of the physical configuration of the semiconductor device 1 of the embodiment will be described with reference to FIG. 5 to FIG. 7.

### Overall Configuration of Semiconductor Device

FIG. 5 is a cross-sectional view of the semiconductor device 1 according to an embodiment, taken along the X direction.

In the present description, both the X direction and the Y direction are directions extending in a plane parallel to the word lines WL. The X direction and the Y direction are orthogonal to each other. In addition, the direction along which the word lines WL are electrically routed may be referred to as a “second direction”, and this second direction is a direction generally extending along the X direction. A direction intersecting with the second direction may be referred to as a “first direction”, and this first direction is the direction extending generally along the Y direction. However, a semiconductor device 1 may have a manufacturing error or tolerance and hence, the first direction and the second direction are not necessarily orthogonal to each other in practice.

As shown in FIG. 5, the semiconductor device 1 includes, in order from the bottom of the drawing page, a semiconductor substrate SB, peripheral circuits CBA, one or more select gate lines SGD, a plurality of word lines WL, one or more select gate lines SGS, a source line SL, and an electrode film EL.

In the present description, the surface of the semiconductor substrate SB on the side on which the peripheral circuits CBA are provided is referred to as the upper surface, and the page direction in which the upper surface of the semiconductor substrate SB faces is referred to as an upward direction in the semiconductor device 1.

The semiconductor substrate SB is, for example, a silicon substrate or the like obtained by dicing a silicon wafer or the like. The peripheral circuits CBA including transistors TR, wirings, and the like are disposed on the surface of the semiconductor substrate SB, and the entire surface of the semiconductor substrate SB is covered by an insulation layer 40. As described above, the peripheral circuits CBA include a sense amplifier module 530 and a row decoder 520 (see FIG. 4). The sense amplifier module 530 includes the sense amplifier circuits SA, each provided for a bit line BL (see FIG. 2, FIG. 3). The row decoder 520 includes a plurality of transistors TR₂₂ provided for the word lines WL.

The word lines WL and the select gate lines SGD, SGS are disposed above the semiconductor substrate SB on which the peripheral circuits CBA and covered by an insulation layer 50. A memory region MR is disposed in a center (middle) portion of the word lines WL in the X direction, and stepped regions SR are disposed at both end portions of the word lines WL in the X direction.

A plurality of pillars PL are disposed in the memory region MR. The pillars PL penetrate through the word lines WL and the select gate lines SGD, SGS, and one end of the pillars PL protrude into the source line SL.

The electrode film EL is disposed above the source line SL via an insulation layer 60. The electrode film EL, excluding a pad region PD, is covered by an insulation layer 70. The pad region PD is provided in a peripheral region PR located outward of the word lines WL in the X direction. The insulation layer 70 has a configuration in which, for example, a silicon oxide layer, a silicon nitride layer, a polyimide layer, and other layers are stacked.

The electrode film EL is connected to the source line SL, a through contact C3, and the like by, for example, plugs PG that penetrate through the insulation layer 60. The through contact C3 is provided in the peripheral region PR and penetrates through the insulation layer 50 and the insulation layer 40 to connect to the semiconductor substrate SB on which the peripheral circuits CBA are disposed.

The semiconductor substrate SB may be controlled to a predetermined potential via the pad region PD and the through contact C3 by an external device outside the semiconductor device 1. Power and signals are supplied to the semiconductor device 1 through the pad region PD from such external devices.

The plurality of memory cells MC (see FIG. 2) are formed at intersections between the pillars PL and the word lines WL. The semiconductor device 1 is thus constituted as a three-dimensional nonvolatile memory in which the memory cells MC are stacked in the memory region MR.

A stepped part SP is disposed in each stepped region SR, the word lines WL and the select gate lines SGD, SGS are formed into a stepped shape, and terminate at the stepped part SP.

Contacts CC are disposed at terrace parts of respective steps formed by the word lines WL and the select gate lines SGD, SGS. The contacts CC extend upward through the insulation layer 50 and are connected to the word lines WL and the select gate lines SGD, SGS in respective layers.

These contacts CC allow the word lines WL and the like, stacked in multiple layers, to be individually routed and addressed. More specifically, a write voltage, a read voltage, or the like can be applied from these contacts CC to the memory cells MC, included in the memory region MR via the word lines WL at the same height positions as the memory cells MC.

The semiconductor device 1 of this embodiment is configured such that the insulation layer 40, which covers the peripheral circuits CBA, and the insulation layer 50, which covers the word lines WL and the like, are laminated to each other. The insulation layers 40, 50 thus serve as lamination layers in this manner. Due to the lamination of the insulation layers 40, 50, electrode pads disposed on the surface of the insulation layer 40 can be connected to electrode pads disposed on the surface of the insulation layer 50 and hence, the peripheral circuits CBA, the contacts CC, the word lines WL, the select gate lines SGS, SGD, and the pillars PL may be electrically connected to each other.

Application of a predetermined voltage to the memory cells MC from the contacts CC is controlled by the peripheral circuits CBA, which are electrically connected to these components. As described above, the peripheral circuits CBA control the electrical operation of the memory cells MC.

### (Physical Configuration of Row Decoder)

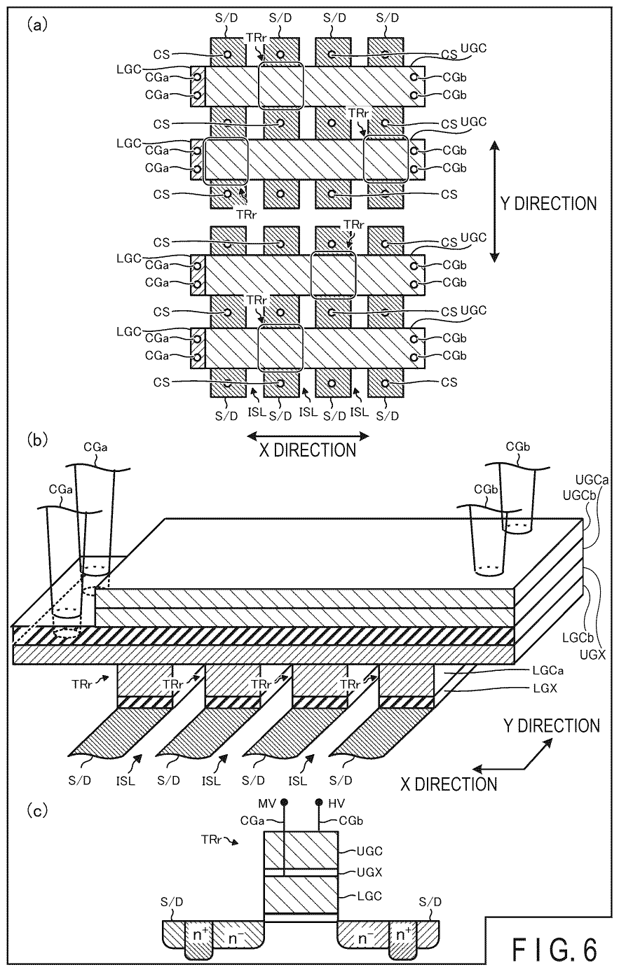

FIG. 6 is a diagram showing an example of the physical configuration of the row decoder 520 of the semiconductor device 1 according to the embodiment. To be more specific, transistors TRr shown in FIG. 6 are the transistors TR₂₂ (see FIG. 4) included in the block selection circuit 22 of the row decoder 520, and FIG. 6 show an example of the physical configuration of the transistors TR₂₂.

FIG. 6, part (a) is a top plan view of the transistors TRr, FIG. 6, part (b) is a perspective view of the transistors TRr, and FIG. 6, part (c) is a schematic view for illustrating the electrical configuration of a transistor TRr.

As shown in FIG. 6, part (a), in the block selection circuit 22, a plurality of source/drain regions S/D are provided in the semiconductor substrate SB. The source/drain regions S/D form a layer of the semiconductor substrate SB that is doped with an impurity having a predetermined conductivity, such as an N type.

These source/drain regions S/D are arranged in the X direction and the Y direction, and extend in the Y direction. The individual source/drain regions S/D are separated by element isolation parts ISL, thus are electrically isolated from each other. The element isolation parts ISL are formed of an insulation material, such as a silicon oxide.

In the block selection circuit 22, the transistors TRr are arranged in an array in the X direction and the Y direction. In this arrangement, some transistors TRr are disposed on the same source/drain region S/D while spaced in the Y direction, thus sharing a source/drain region S/D.

These transistors TRr include a lower gate electrode LGC and an upper gate electrode UGC. These gate electrodes LGC, UGC extend in the X direction. Consequently, the transistors TRr arranged with each other along the X direction share these gate electrodes LGC, UGC. In the example shown in FIG. 6, part (a), four transistors TRr arranged in the X direction share a common gate electrode LGC and a common gate electrode UGC.

A contact CS is connected to each source/drain region S/D at a position between two individual transistors TRr spaced in the Y direction. Of these contacts CS, each contact CS located between the transistors TRr in the Y direction and that share the same source/drain region S/D is connected to the voltage generation circuit 380 via the voltage selection circuit 23 (see FIG. 4). Each of the contacts CS disposed at both end portions of the individual source/drain region S/D in the Y direction is connected to a different word line WL or to the select gate line SGD, SGS.

One or a plurality of contacts CGa are connected to one end portion in the X direction of the gate electrode LGC that is shared by a plurality of transistors TRr. One or a plurality of contacts CGb are connected to the other end in the X direction portion of the gate electrode UGC that is shared by a plurality of transistors TRr. In the example shown in FIG. 6, part (a), two contacts CGa are connected to the gate electrode LGC, and two contacts CGb are connected to the gate electrode UGC.

These contacts CGa, CGb are connected to the address decoder 21 (see FIG. 4) and apply an on-voltage to the gate electrodes LGC, UGC of the transistors TRr.

As shown in FIG. 6, part (b), the gate electrode LGC has a multilayer structure in which a plurality of gate electrodes LGCa, LGCb are stacked, and the gate electrode UGC has a multilayer structure in which a plurality of gate electrodes UGCa, UGCb are stacked.

To be more specific, each individual transistor TRr includes, from the source/drain region S/D, a gate insulation layer LGX, the gate electrodes LGCa, LGCb, a gate insulation layer UGX, and the gate electrodes UGCa, UGCb in this order. The gate insulation layers LGX, UGX are silicon oxide layers, for example. The gate electrodes LGCa, LGCb, UGCa, UGCb are polysilicon layers, for example.

Of these layers, the gate insulation layer LGX is provided independently for each of the plurality of transistors TRr arranged in the X direction. That is, each of these transistors TRr includes a separate gate insulation layer LGX. In contrast, the gate electrode LGCb, the gate insulation layer UGX, and the gate electrodes UGCa, UGCb are shared by the plurality of transistors TRr arranged in the X direction.

Of the lower gate electrodes LGCa, LGCb, the gate electrode LGCa is provided on the individual gate insulation layer LGX in an isolated manner for each of the plurality of transistors TRr arranged in the X direction. However, the gate electrode LGCa and the gate electrode LGCb are in contact, and thus are electrically connected and hence, it can be regarded that these gate electrodes LGCa, LGCb, as a whole, are shared by the plurality of transistors TRr arranged in the X direction.

Each of the gate electrode LGCb and the gate insulation layer UGX has, at one end portion thereof in the X direction, a region that does not overlap in the up-down direction with the gate electrodes UGCa, UGCb disposed above the gate electrode LGCb and the gate insulation layer UGX and, in this region, the contacts CGa penetrate through the gate insulation layer UGX, and are connected to the gate electrode LGCb. The contacts CGb at the other end portion in the X direction are directly connected to the gate electrode UGCb in the uppermost layer forming the uppermost layer.

When such a transistor TRr is schematically shown, as shown in FIG. 6, part (c), the above-mentioned transistor TRr is configured to have two gate insulation layers UGX, LGX with the upper and lower gate electrodes UGC, LGC interposed therebetween. Consequently, it is possible to cause the transistor TRr to perform a different operation depending on whether a high voltage HV is applied from the contacts CGb connected to the gate electrode UGC or a medium voltage MV is applied from the contacts CGa connected to the gate electrode LGC.

At this point of operation, regarding the plurality of transistors TRr that are arranged in the X direction and that share one gate electrode UGC and one gate electrode LGC, these gate electrodes UGC, LGC have the same potential. Accordingly, these transistors TRr form a transistor group that corresponds to some or all of the word lines WL and the select gate lines SGD, SGS that are included in one block BLK (see FIG. 4).

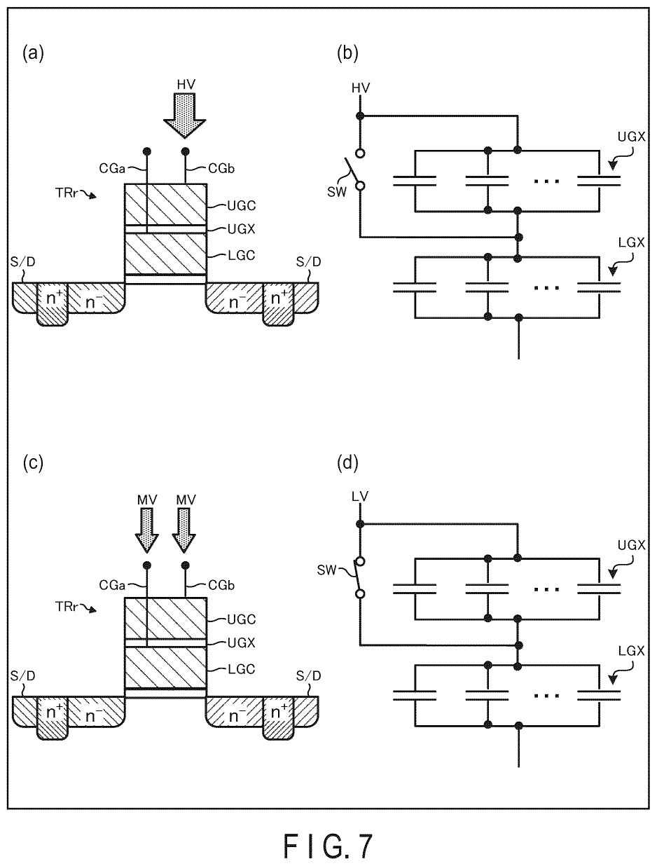

FIG. 7 is a schematic view for illustrating electrical operations of a transistor TRr according to the embodiment.

FIG. 7 shows a schematic view of a transistor TRr during operation of the transistor TRr in writing data into the memory cell MC, and an equivalent circuit showing the capacitances of the gate insulation layers UGX, LGX of the transistor TRr at that time.

As shown in FIG. 7, part (a), in writing data into the memory cell MC, as an on-voltage that turns on the transistor TRr, a high voltage HV is applied from the contacts CGb connected to the gate electrode UGC and the contacts CGa connected to the gate electrode LGC. Consequently, the lower gate electrode LGC is brought into a floating state, and thus the transistor TRr may be operated as a high breakdown voltage transistor that includes the gate electrode UGC and a gate insulation layer having a thickness of two layers, that is, the two gate insulation layers UGX, LGX.

A write voltage is applied, via the contacts CS, to the source/drain region S/D at a portion between two transistors TRr arranged in the Y direction, and is transferred to the memory cell MC (a writing target), via the contacts CS disposed on the other side of the source/drain region S/D, and via the word lines WL to which the contacts CS are connected.

A transistor to which a high voltage HV is applied in this manner, and which has a high breakdown voltage is also referred to as “high voltage (HV)-MOS transistor”.

When the gate capacitance of the transistor TRr is expressed by an equivalent circuit, as shown in FIG. 7(part b), the gate insulation layers UGX, LGX are considered to be connected in parallel in each of the transistors TRr that are arranged in the X direction and that share one gate electrode UGC and one gate electrode LGC. The gate insulation layers UGX and the gate insulation layers LGX are connected in series with one another.

When the transistor TRr is being operated as an HV-MOS transistor, a switch SW of the equivalent circuit is opened, so that it can be regarded that the lower gate electrode LGC is in an open state. Therefore, from the upper gate electrode UGC, it is observed that the gate insulation layer has an effective thickness of two layers, that is, the gate insulation layers UGX, LGC.

FIG. 7, in part (c) and part (d) show a schematic view of the transistor TRr showing the operation of the transistor TRr in reading data from the memory cell MC, and an equivalent circuit showing the capacitances of the gate insulation layers UGX, LGX of the transistor TRr at that time.

As shown in FIG. 7, part (c), in reading data from the memory cell MC, as an on-voltage that turns on the transistor TRr, a medium voltage MV is applied from both of the contacts CGb connected to the gate electrodes UGC and the contacts CGa connected to the gate electrodes LGC. The medium voltage MV is a voltage lower than the high voltage HV. Consequently, the transistor TRr is operated as a medium breakdown voltage transistor that includes the lower gate electrode LGC, and the gate insulation layer LGX that corresponds to the gate electrode LGC.

A read voltage is applied, via the contacts CS, to the source/drain region S/D at a portion between two transistors TRr arranged in the Y direction, and is transferred to the memory cell MC, being a reading target, via the contacts CS disposed on the other side of the source/drain region S/D, and via the word lines WL to which the contacts CS are connected.

A transistor to which a medium voltage MV is applied in this manner, and which has a medium breakdown voltage is also referred to as “medium voltage (MV)-MOS transistor”.

When the transistor TRr is being operated as an MV-MOS transistor, as shown in FIG. 7(part d), the switch SW of the equivalent circuit is closed, so that it can be regarded that the medium voltage MV is also applied to the lower gate electrode LGC. Therefore, the transistor TRr is mainly controlled by the lower gate electrode LGC.

### Method for Manufacturing Semiconductor Device

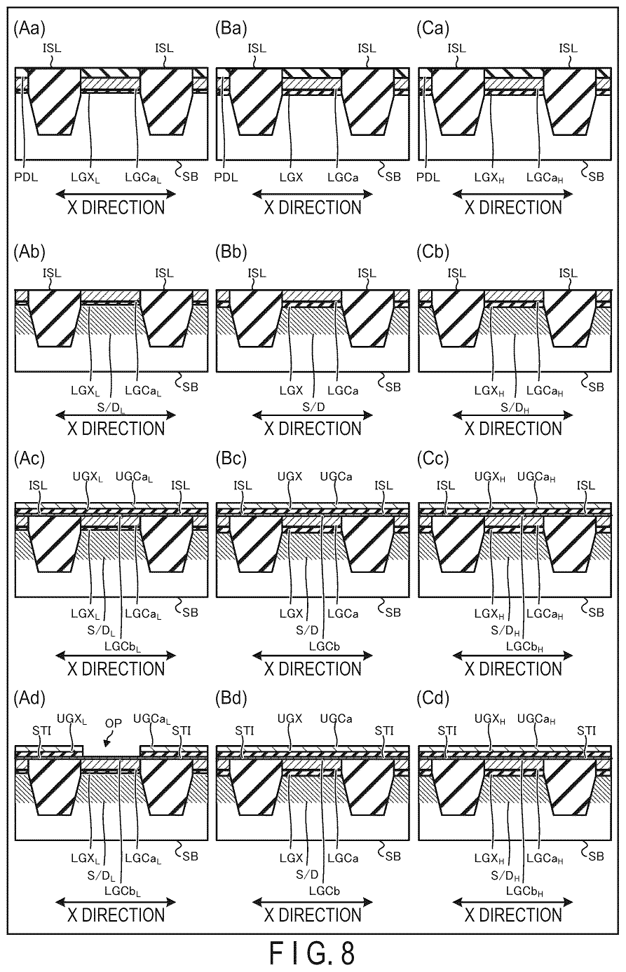

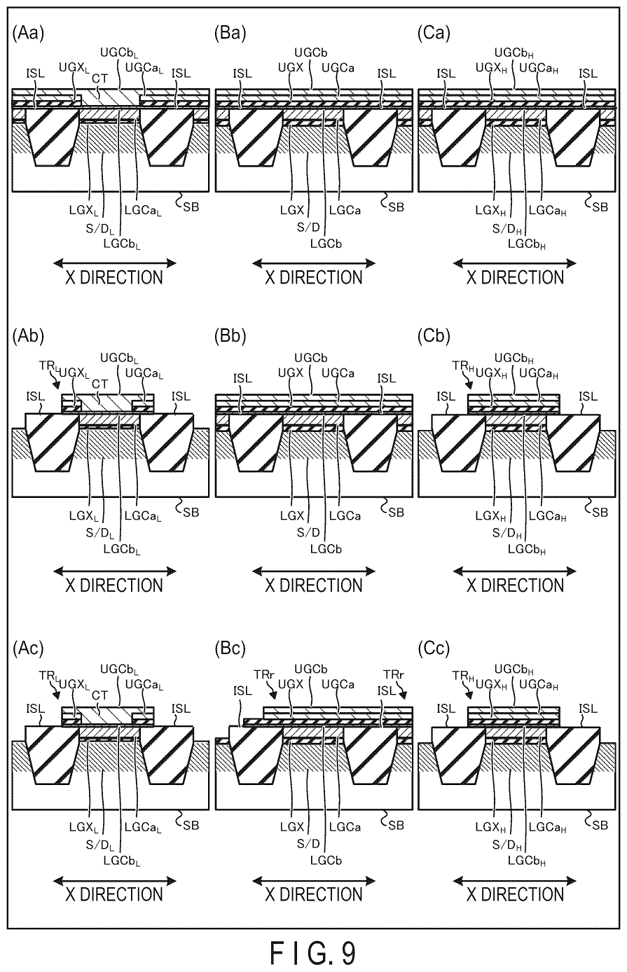

Next, a method for manufacturing semiconductor device 1 will be described with reference to FIG. 8 and FIG. 9.

FIG. 8 and FIG. 9 provide cross-sectional views, taken along the X direction, illustrating aspects of the method for manufacturing the semiconductor device 1 according to the embodiment in order. To be more specific, portions labeled with a capital letter (A) in FIG. 8 and FIG. 9 are views of a transistor TR_{L}, portions labeled with a capital letter (B) are views of the transistor TRr, and portions labeled with a capital letter (C) are views of a transistor TR_{H}.

The transistor TR_{L} is a LV-MOS transistor to which a low voltage (LV) is applied, and that has a low breakdown voltage. The low voltage is a voltage even lower than the medium voltage MV applied to the transistor TRr. The transistor TR_{H} is an HV-MOS transistor to which a high voltage (HV) is applied, and that has a high breakdown voltage. The high voltage applied to the transistor TR_{H} may be substantially equal to the high voltage HV applied to the transistor TRr.

FIG. 8 and FIG. 9 show aspects of methods for manufacturing the transistors TR_{L}, TRr, TR_{H}.

As shown in the part (Aa) of FIG. 8, a gate insulation layer LGX_{L} (a silicon oxide layer or the like), a gate electrode LGCa_{L} (a polysilicon layer or the like), and a pad layer PDL (a silicon nitride layer or the like) are formed on a semiconductor substrate SB in this order.

The gate insulation layer LGX_{L} becomes the gate insulation layer of the transistor TR_{L} later. The gate electrode LGCa_{L} becomes a portion of the lower gate electrode of the transistor TR_{L} later. The pad layer PDL becomes a cover layer later in forming a source/drain region S/D_{L} of the transistor TR_{L} on the semiconductor substrate SB. At this point of operation, these layers are formed in such a way as to cover the entire region including a region where the source/drain region S/D_{L} is to be formed.

As shown in the part (Ba) of FIG. 8, a gate insulation layer LGX and a gate electrode LGCa of the transistor TRr, and a pad layer PDL are formed on the semiconductor substrate SB in this order. These layers are also formed in such a way as to cover the entire region including a region where a source/drain region S/D of the transistor TRr is to be formed.

As shown in the part (Ca) of FIG. 8, a gate insulation layer LGX_{H} (a silicon oxide layer or the like), a gate electrode LGCa_{H} (a polysilicon layer or the like), and a pad layer PDL are formed on the semiconductor substrate SB in this order.

The gate insulation layer LGX_{H} becomes the lower gate insulation layer of the transistor TR_{H} later. The gate electrode LGCa_{H} becomes a portion of the lower gate electrode of the transistor TR_{H} later. At this point of operation, these layers are also formed in such a way as to cover the entire region including a region where a source/drain region S/D_{H} of the transistor TR_{H} is to be formed.

The gate insulation layer LGX_{L} of the transistor TR_{L} is a layer having a smaller thickness than the gate insulation layer LGX of the transistor TRr. However, the gate insulation layer LGX_{H} of the transistor TR_{H} can be caused to have a thickness substantially equal to the thickness of the gate insulation layer LGX of the transistor TRr, for example. Accordingly, the gate insulation layer LGX_{L} of the transistor TR_{L} is formed in a step different from a step for forming the gate insulation layer LGX of the transistor TRr and the gate insulation layer LGX_{H} of the transistor TR_{H}.

Other gate electrodes LGCa_{L}, LGCa, LGCa_{H}, and the pad layer PDL can be collectively formed in these transistors TR_{L}, TRr, TR_{H}. Further, respective layers formed thereafter on the upper layer side may also be collectively formed in the transistors TR_{L}, TRr, TR_{H}.

As shown in part (Aa) to the part (Ca) of FIG. 8, element isolation parts ISL are formed to electrically isolate regions where these transistors TR_{L}, TRr, TR_{H} are to be formed. Each element isolation part ISL is formed by forming a groove and then filling the groove with a silicon oxide layer or the like. The groove may penetrate through the pad layer PDL, the gate electrode LGCa_{L}, LGCa, LGCa_{H}, and the gate insulation layer LGX_{L}, LGX, LGX_{H}to reach a predetermined depth in the semiconductor substrate SB.

Thereafter, an impurity (dopant) having a predetermined conductivity, such as an N-type impurity, is doped into each region between the element isolation parts ISL via the pad layer PDL.

As shown in the part (Ab) to the part (Cb) of FIG. 8, due to the above-mentioned doping, the source/drain regions S/D_{L}, S/D, S/D_{H} are respectively formed in the regions where the transistors TR_{L}, TRr, TR_{H} are to be formed. Thereafter, the pad layer PDL is removed.

As shown in the part (Ac) of FIG. 8, a gate electrode LGCb_{L} (a polysilicon layer or the like), a gate insulation layer UGX_{L} (a silicon oxide layer or the like), and a gate electrode UGCa_{L} (a polysilicon layer or the like) are formed on the gate electrode LGCa_{L} in this order.

The gate electrode LGCb_{L} becomes a portion of the lower gate electrode of the transistor TR_{L} later. Although the gate insulation layer UGXL constitutes a portion of the transistor TR_{L} later, as will be described later, the gate insulation layer UGX_{L} does not contribute to the electrical operation of the transistor TR_{L}. The gate electrode UGCa_{L} becomes a portion of the upper gate electrode of the transistor TR_{L} later. At this point of operation, these layers are formed in such a way as to cover the entire region including the source/drain region S/D_{L} and the element isolation parts ISL.

As shown in the part (Bc) of FIG. 8, a gate electrode LGCb, a gate insulation layer UGX, and a gate electrode UGCa of the transistor TRr are formed on the gate electrode LGCa in this order. These layers are also formed in such a way as to cover the entire region including the source/drain region S/D of the transistor TRr and the element isolation parts ISL.

As shown in the part (Cc) of FIG. 8, a gate electrode LGCb_{H} (a polysilicon layer or the like), a gate insulation layer UGX_{H} (a silicon oxide layer or the like), and a gate electrode UGCa_{H} (a polysilicon layer or the like) are formed on the gate electrode LGCa_{H} in this order.

The gate electrode LGCb_{H} becomes a portion of the lower gate electrode of the transistor TR_{H} later. The gate insulation layer UGX_{H} becomes the upper gate insulation layer of the transistor TR_{H} later. The gate electrode UGCa_{H} becomes a portion of the upper gate electrode of the transistor TR_{H} later. At this point of operation, these layers are also formed in such a way as to cover the entire region including the source/drain region S/D_{H} and the element isolation parts ISL.

As shown in the part (Ad) of FIG. 8, portions of the gate electrode LGCb_{L}, the gate insulation layer UGX_{L}, and the gate electrode UGCa_{L} on the source/drain region S/D_{L} are removed to form an opening part OP. At this point of operation, the gate electrode LGCb_{L}, the gate insulation layer UGX_{L}, and the gate electrode UGCa_{L} are removed such that the area of the opening part OP when viewed from above is smaller than the area to be later occupied by the gate electrodes LGCa_{L}, LGCb_{L}, and the like in the transistor TR_{L}.

As shown in the part (Aa) of FIG. 9 to the part (Ca) of FIG. 9, gate electrodes UGCb_{L}, UGCb, UGCb_{H}, each of which is a polysilicon layer or the like, are respectively formed in the regions where the transistors TR_{L}, TRr, TR_{H} are to be formed. The gate electrodes UGCb_{L}, UGCb_{H} become portions of the upper gate electrodes of the transistors TR_{L}, TR_{H}.

Consequently, in the region where the transistor TR_{L} is to be formed, the opening part OP is also filled with a polysilicon layer or the like so that a contact part CT is formed in which the gate electrode UGCb_{L} and the gate electrode LGCa_{L} are connected to each other. Thus, in the transistor TR_{L}, the upper gate electrodes UGCa_{L}, UGCb_{L} are electrically connected to the lower gate electrodes LGCa_{L}, LGCb_{L}.

In contrast, in the region where the transistor TRr is to be formed, the gate insulation layer UGX is interposed between the gate electrode UGCa and the gate electrode LGCb over the entire region. Therefore, in the transistor TRr, the upper gate electrodes UGCa, UGCb are electrically divided from the lower gate electrodes LGCa, LGCb by the gate insulation layer UGX.

In the same manner, in the region where the transistor TR_{H} is to be formed, the gate insulation layer UGX_{H} is interposed between the gate electrode UGCa_{H} and the gate electrode LGCb_{H} over the entire region. Therefore, also in the transistor TR_{H}, the upper gate electrodes UGCa_{H}, UGCb_{H} are electrically divided from the lower gate electrodes LGCa_{H}, LGCb_{H} by the gate insulation layer UGX.

As shown in the part (Ab) of FIG. 9, in the region where the transistor TR_{L} is to be formed, portions of the gate electrodes UGCa_{L}, UGCb_{L}, the gate insulation layer UGX_{L}, and the gate electrode LGCb_{L} are removed to cause these respective layers to have the shape of a transistor TR_{L}.

Thereafter, a contact connected to the gate electrode UGCb_{L} and contacts connected to the source/drain regions S/D_{L} located on both sides in the Y direction of the respective layers including the gate electrode UGCb_{L} are formed.

With the above-mentioned operations, the transistor TR_{L} is formed in a region electrically isolated by the element isolation parts ISL.

As shown in the part (Cb) of FIG. 9, in the region where the transistor TR_{H} is to be formed, portions of the gate electrodes UGCa_{H}, UGCb_{H}, the gate insulation layer UGX_{H}, and the gate electrode LGCb_{H} are removed to cause these respective layers to have the shape of a transistor TR_{H}.

Thereafter, a contact connected to the gate electrode UGCb_{H} and contacts connected to the source/drain regions S/D_{H} located on both sides in the Y direction of the respective layers including the gate electrode UGCb_{H} are formed.

With the above-mentioned operations, the transistor TR_{H} is formed within a region electrically isolated by the element isolation parts ISL.

By causing the gate insulation layer LGX_{L}, which does not contribute to the electrical operation of the transistor TR_{L}, to be interposed in the region where the transistor TR_{L} is to be formed as described above, the transistor TR_{L} and the transistor TR_{H} have the same layer structure. Accordingly, transistors TR_{L}, TR_{H} can be easily formed together.

As shown in the part (Bc) of FIG. 9, in the region where the transistor TRr is to be formed, portions of the gate electrodes UGCa, UGCb are removed to expose one end portion in the X direction of the gate electrode LGCb covered by the gate insulation layer UGX.

Thereafter, contacts CGb connected to the gate electrode UGCb are formed. In addition, contacts CGa are formed at the portion from which the portions of the gate electrodes UGCa, UGCb were removed. The contacts CGa penetrate through the gate insulation layer UGX and are connected to the gate electrode LGCb. Further, contacts CS are formed connected to the source/drain regions S/D located on both sides in the Y direction of the respective layers including these gate electrodes UGCb, LGCb.

With the above-mentioned operations, a transistor TRr can be formed that includes the gate electrodes LGCa, LGCb, UGCa, UGCb, and the like extending in the X direction across the region electrically isolated by the element isolation parts ISL.

Thereafter, the transistors TR_{L}, TRr, TR_{H}, and the like can be connected to each other by upper wirings or the like to form peripheral circuits CBA including the row decoder 520 and, after the peripheral circuits CBA are covered by an insulation layer 40 (see FIG. 5), electrode pads electrically connected to the peripheral circuits CBA are formed on the surface of the insulation layer 40.

In contrast, the above-described configuration that includes the word lines WL, the pillars PL, and the like may be formed as described below.

A source line SL is formed on a support substrate, such as a silicon substrate. Then, a plurality of sacrificial layers and a plurality of insulation layers are alternately stacked and, thereafter, both end portions in the X direction of these layers are formed into a stepped shape. In addition, pillars PL which penetrate through the plurality of sacrificial layers and the plurality of insulation layers are formed, and these layers are then covered by an insulation layer 50. Thereafter, the sacrificial layers are replaced with tungsten layers or the like to form the word lines WL and select gate lines SGD, SGS. In addition, a plurality of contacts CC are formed that penetrate through the insulation layer 50, and that are connected to stepped parts SP (see FIG. 5), at which the individual word lines WL are formed into a stepped shape. Further, a bit line BL layer is formed above the pillars PL, a wiring layer is formed above the contacts CC, and other wiring layers are formed, and electrode pads that are electrically connected to these layers are then formed on the surface of the insulation layer 50.

Thereafter, the support substrate and the semiconductor substrate SB are laminated (bonded) to each other to connect the electrode pads in the insulation layers 50, 40 to each other. After the support substrate and the semiconductor substrate SB are laminated to each other, excess portions of the support substrate may be removed to expose the source line SL, and an electrode film EL is then connected to the source line SL via an insulation layer 60, in which plugs PG are formed.

With the above-mentioned operations, the semiconductor device 1 of the embodiment is manufactured.

### SUMMARY

A semiconductor device, such as a three-dimensional nonvolatile memory, includes peripheral circuits that control the electrical operations of the memory cells. The peripheral circuits include a plurality of transistors formed on a semiconductor substrate. The required properties of some of these transistors may change each time due to a difference in transfer voltage that may occur sometimes. For example, in writing data into the memory cells, transistors used in the block selection circuit of the row decoder have a high transfer voltage, and thus are required to have a high breakdown voltage. In contrast, in reading data from the memory cells, the transistors have a low transfer voltage, and it is desirable for the transistors to be driven at a relatively low on-voltage, such as a medium voltage.

Generally, the number of transistors included in each peripheral circuit is increasing due to an increase in the storage capacity of semiconductor devices, and due to a demand for a reduction in size of the semiconductor devices and hence, it is desirable to arrange these transistors at a narrow pitch. However, it is difficult to reduce a pitch in the gate width direction (that is, in the X direction) for transistors that have a high transfer voltage, and thus are required to have a high breakdown voltage.

The semiconductor device 1 includes transistors TRr in which the gate insulation layer LGX, the gate electrode LGC, the gate insulation layer UGX, and the gate electrode UGC are stacked, the contacts CGa connected to the gate electrode LGC, and the contacts CGb connected to the gate electrode UGC. Consequently, depending on whether the required transfer voltage is high or low, it is possible to cause the transistors TRr to serve as HV-MOS transistors or MV-MOS transistors. Thus, the transistors TRr can cope with various processing or operation details.

In the semiconductor device 1 of the present embodiment, one side of each source/drain region S/D in the Y direction with respect to the gate insulation layer LGX of the transistor TRr is connected to a word line WL. Consequently, these transistors TRr can be used as the transistors TR₂₂ included in the block selection circuit 22 of the row decoder 520.

In the semiconductor device 1 of the present embodiment, the sequencer 360 applies a high voltage HV to the transistors TRr via the contacts CGb when writing data into the memory cells MC, whereas the sequencer 360 applies a medium voltage MV to the transistors TRr via the contacts CGa when reading data from the memory cells MC. Consequently, it is possible to cause the transistors TRr to serve as HV-MOS transistors for writing data and also as MV-MOS transistors for reading data.

The semiconductor device 1 of the present embodiment further includes a transistor TRr that shares the gate electrode LGC with another transistor TRr that is disposed in the X direction from the transistor TRr. By sharing the gate electrode LGC between a plurality of transistors TRr connected to the word lines WL or the like that belong to, for example, the same block BLK as described above, it is sufficient to dispose the contacts CGa (which apply an on-voltage to the gate electrode LGC) at one end portion in the X direction of the gate electrode LGC, and hence, it is possible to arrange these transistors TRr at a narrow pitch (narrow spacing) in the X direction.

In the semiconductor device 1 of the embodiment, the transistor TRr that shares the gate electrode LGC with another transistor TRr also shares the gate electrode UGC with the other transistor TRr. Consequently, by also disposing the contacts CGb (which apply an on-voltage to the gate electrode UGC) at the other end portion in the X direction of the gate electrode UGC, it is possible to arrange, at an even narrower pitch in the X direction, the plurality of transistors TRr connected to the same word lines WL or the like and belong to the same block BLK.

In the semiconductor device 1, the gate electrode LGC has, at one end portion thereof in the X direction, a region that does not overlap in the up-down direction with the gate electrode UGC. Consequently, it is possible for the contacts CGa to be connected to this region.

### MODIFICATIONS

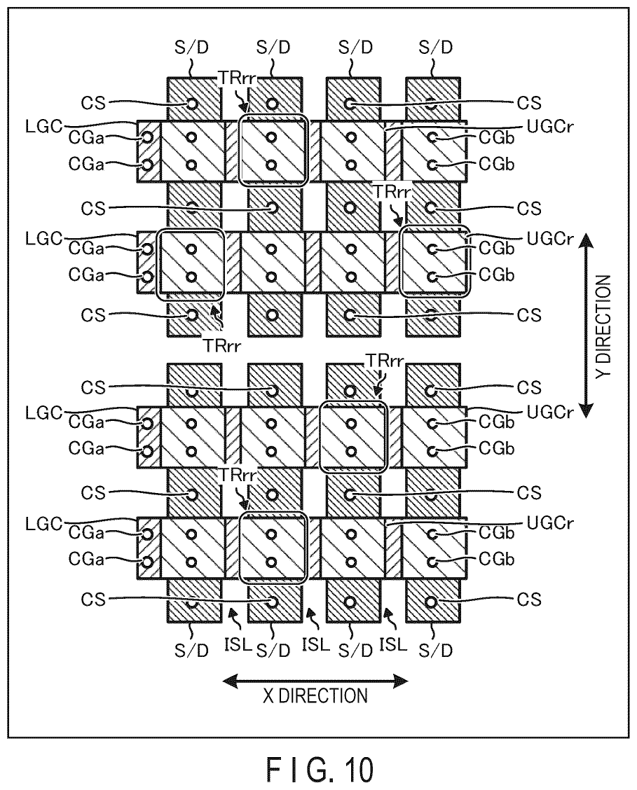

Next, semiconductor devices of modifications 1 to 3 will be described with reference to FIG. 10 to FIG. 12.

### Modification 1

FIG. 10 is a top plan view of transistors TRrr included in a row decoder of a semiconductor device according to a modification 1 of an embodiment. The transistor TRrr of the modification 1 may also correspond to the transistor TR₂₂ (see FIG. 4), but differs from the transistor TRr of the above-described embodiment in that the transistor TRrr includes an individually independent gate electrode UGCr.

In FIG. 10, the same reference symbols are given to components substantially the same as the components in the above-described embodiment, and the description of such components may be omitted.

As shown in FIG. 10, in the same manner as the transistor TRr described above, the transistors TRrr of the modification 1 include a gate electrode LGC extending in the X direction. The transistors TRrr, like the transistors TRr, arranged with one another in the X direction share this gate electrode LGC. However, each transistor TRrr includes an individually independent gate electrode UGCr, and one or a plurality of contacts CGb are connected to each gate electrode UGCr of the individual transistor TRrr.

In the same manner as the above-described embodiment, one or a plurality of contacts CGa are connected to, for example, one end portion in the X direction of the gate electrode LGC extending in the X direction. However, in the configuration of the modification 1, the contacts CGa may be connected to the gate electrode LGC at another position provided that the position is not covered by the upper gate electrodes UGCr that are individually and independently provided.

In the same manner as the transistors TRr of the above-described embodiment, the plurality of transistors TRrr arranged in the X direction may share an upper gate insulation layer UGX extending in the X direction or may each include an individually independent upper gate insulation layer.

In the semiconductor device of the modification 1, a transistor TRr that shares the gate electrode LGC with a transistor TRrr includes the gate electrode UGCr at a position above the shared gate electrode LGC. The gate electrode UGCr is disposed independently from the gate electrode UGCr of the transistor TRrr.

Also with such a configuration, it is possible to cause the transistors TRrr to serve as HV-MOS transistors in writing data and also to serve as MV-MOS transistors in reading data and hence, the transistors TRrr can cope with various processing and operation details.

In addition, regarding the plurality of transistors TRrr connected to word lines WL or the like that belong to the same block BLK, it is sufficient to dispose the contacts CGa (which apply an on-voltage to the gate electrode LGC) at one end portion in the X direction of the gate electrode LGC. Hence, it is possible to arrange these transistors TRrr at a narrow pitch in the X direction.

In addition, the semiconductor device of the modification 1 can also obtain advantageous effects substantially similar to the advantageous effects of the above-described embodiment.

### Modification 2

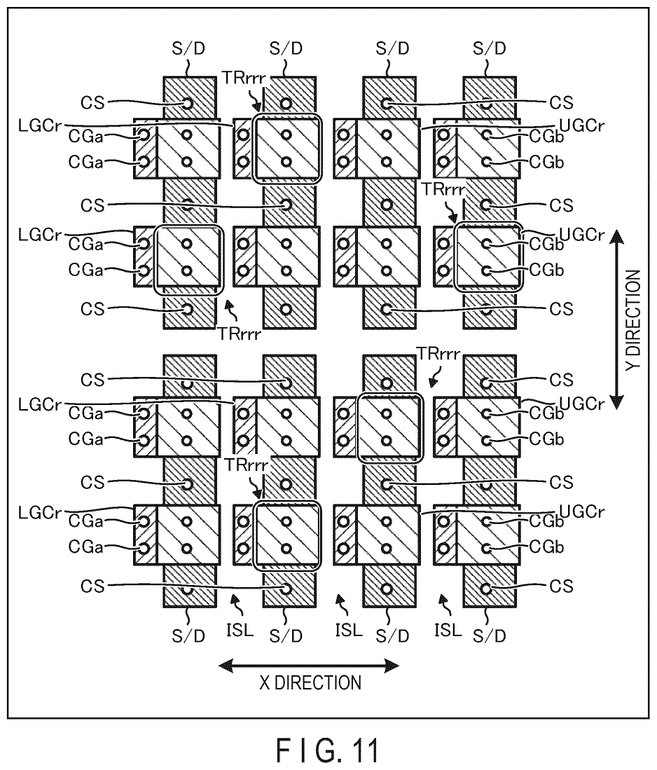

FIG. 11 is a top plan view of transistors TRrrr included in a row decoder of a semiconductor device according to the modification 2. The transistor TRrrr of the modification 2 corresponds to the transistor TR₂₂ (see FIG. 4) but differs from the transistor TRr in that the transistor TRrrr includes individually independent gate electrodes UGCr, LGCr.

In FIG. 11, the same reference symbols are given to components substantially the same as the components in the above-described embodiment, and the description of such components may be omitted.

As shown in FIG. 11, each transistor TRrrr of the modification 2 includes an individually independent gate electrode UGCr and an individually independent gate electrode LGCr. Each gate electrode LGCr of an individual transistor TRrrr has, on one side thereof in the X direction, a region that does not overlap with the gate electrode UGCr in the up-down direction. One or a plurality of contacts CGa connected to each individual gate electrode LGCr can be disposed in this region that is located on the one side of the individual gate electrode LGCr in the X direction and that does not overlap with the gate electrode UGCr.

Also in the configuration of the semiconductor device of the modification 2, it is possible to cause the transistors TRrrr to serve as HV-MOS transistors in writing data and also to serve as MV-MOS transistors in reading data and hence, the transistors TRrrr can cope with various processing and operation details.

In addition, the semiconductor device of the modification 2 can also obtain advantageous effects substantially similar to the advantageous effects of the above-described embodiment.

### Modification 3

In the above-described embodiment and modifications 1, 2, the transistors TRr, TRrr, TRrrr are used as the transistors TR₂₂ (see FIG. 4) included in the block selection circuit 22 of the row decoder 520. However, it is also possible to use these transistors TRr, TRrr, TRrrr that perform a different operation depending on whether the required transfer voltage for other uses.

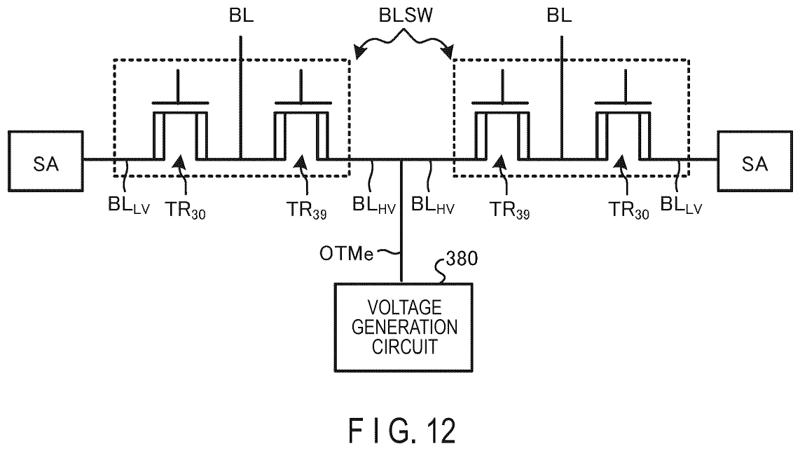

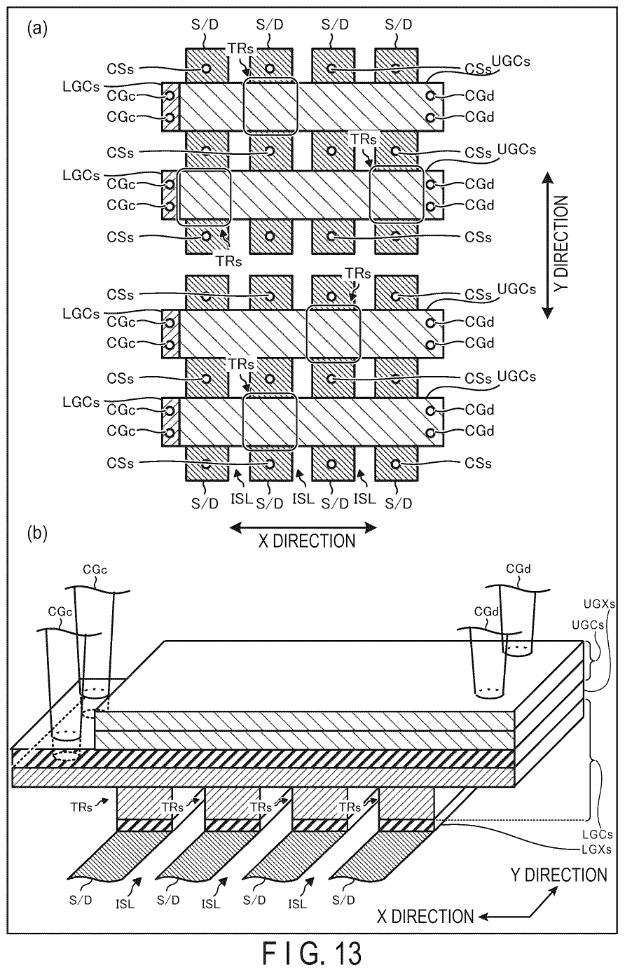

In the modification 3, an application example different from the above-described examples will be described with reference to FIG. 12 and FIG. 13.

In drawings, the same reference symbols are given to components substantially the same as the components in the above-described embodiment, and the description of such components may be omitted.

In a three-dimensional nonvolatile memory, such as the semiconductor device 1, a high voltage is applied to the bit lines BL to extract a charge current from the drain side for erasing data. In contrast, in reading data, a low voltage is applied to the bit lines BL connected to the sense amplifier circuit SA. Thus, it is necessary to apply different voltages, (that is, a high voltage or a low voltage) to the bit lines BL for erasing and reading data from the memory cells MC.

FIG. 12 is an equivalent circuit diagram showing an example of the configuration of bit line selection circuits BLSW in which transistors of an embodiment are used.

As shown in FIG. 12, to apply different voltages, that is, a high voltage and a low voltage, to predetermined bit lines BL, there may be cases in which the bit line selection circuit BLSW is disposed between the voltage generation circuit 380 and an individual sense amplifier circuit SA.

A bit line selection circuit BLSW can be provided for each bit line BL connected to the memory cells MC and includes two transistors TR₃₀, TR₃₉. The transistor TR₃₀ is connected to the sense amplifier circuit SA via a low-voltage bit line BL_{LV}, and the transistor TR₃₉ is connected to the voltage generation circuit 380 via a high-voltage bit line BL_{HV} and a voltage output terminal OTMe. The corresponding bit line BL is connected to the low-voltage bit line BL_{LV} or to the high-voltage bit line BL_{HV} by one of the two transistors TR₃₀, TR₃₉. A low voltage is transferred from the sense amplifier circuit SA, and an erase voltage, which is a high voltage, is transferred from the voltage generation circuit 380.

That is, in performing an erase operation, the transistor TR₃₉ on the high voltage side is turned on, and the transistor TR₃₀ on the low voltage side is turned off. Consequently, the corresponding bit line BL is connected to the high-voltage bit line BL_{HV}. In performing a read operation, the transistor TR₃₀ on the low voltage side is turned on, and the transistor TR₃₉ on the high voltage side is turned off. Consequently, the corresponding bit line BL is connected to the low-voltage bit line BL_{LV}.

In the modification 3, each of these transistors TR₃₀, TR₃₉ can be a transistor that performs a different operation depending on whether the transfer voltage is high or low.

FIG. 13 is a diagram showing an example of the physical configuration of the transistors TRs included in a bit line selection circuit BLSW of a semiconductor device according to the modification 3. To be more specific, FIG. 13, part (a) is a top plan view of the transistors TRs, and FIG. 13, part (b) is a perspective view of the transistors TRs.

As shown in FIG. 13, part (a), in the same manner as the transistors TRr of the above-described embodiment, each transistor TRs of the modification 3 includes lower and upper gate electrodes LGCs, UGCs which extend in the X direction, and a plurality of transistors TRs (arranged in the X direction) share these gate electrodes LGCs, UGCs.

A contact CSs is connected to each source/drain region S/D at a position between two individual transistors TRs spaced in the Y direction. Each contact CSs located between these transistors TRs spaced in the Y direction and that share one source/drain region S/D is connected to a same bit line BL.

Regarding contacts CSs disposed at both end portions of the individual source/drain region S/D in the Y direction, one contact CSs is connected to the low-voltage bit line BL_{LV}, and the other contact CSs is connected to the high-voltage bit line BL_{HV}.

That is, of the transistors TRs that are arranged in the Y direction and that share the same source/drain region S/D, the transistor TRs close to the contact CSs connected to the low-voltage bit line BL_{LV} corresponds to the transistor TR₃₀, and the transistor TRs close to the contact CSs connected to the high-voltage bit line BL_{HV} corresponds to the transistor TR₃₉.

One or a plurality of contacts CGc are connected to one end portion in the X direction of the gate electrode LGCs that is shared by a plurality of transistors TRs. One or a plurality of contacts CGd are connected to the other end portion in the X direction of the gate electrode LGCs that is shared by the plurality of transistors TRs. An on-voltage that turns on the transistors TRs is applied from these contacts CGc, CGd.

As shown in FIG. 13, part (a), each transistor TRs of the modification 3 also includes a gate insulation layer LGXs and a gate insulation layer UGXs. The gate insulation layer LGXs is sandwiched between the gate electrode LGCs and the source/drain region S/D. The gate insulation layer UGXs is sandwiched between the gate electrodes LGCs, UGCs.

As in the case of the transistor TRrr of the modification 1, the transistors TRs of the modification 3 may be configured such that, of the upper and lower gate electrodes, only the lower gate electrode is shared by transistors TRs arranged in the X direction. Alternatively, as in the case of the transistor TRrrr of the modification 2, the transistors TR of the modification 3 may be configured such that both the upper and lower gate electrodes are individually independent. That is, the transistors TRrr and/or transistors TRrrr may be adopted for use in modification 3 as the transistors TRs.

The semiconductor device of the modification 3 can use transistors that perform a different operation depending on whether the transfer voltage is high or low. Thus, the transistors TRs in modification 3 can cope with various processing details.

In the semiconductor device of the modification 3, one side of the source/drain region S/D in the Y direction with respect to the gate insulation layer LGXs can be connected to the bit line BL. Consequently, it is possible to use the transistors TRs for the transistors TR₃₀, TR₃₉ included in a bit line selection circuit BLSW.

In the semiconductor device of the modification 3, the source/drain region S/D on a side opposite to the bit line BL with respect to the gate insulation layer LGXs of a transistor TRs is connected to the voltage output terminal OTMe, and the source/drain region S/D on a side opposite to the bit line BL with respect to the gate insulation layer LGXs of another transistor TRs is connected to the sense amplifier circuit SA.

Consequently, transistors TR₃₀, TR₃₉ for high voltage and low voltage can be transistors TRs having the same configuration. Accordingly, the transistors of a peripheral circuit can be more efficiently formed and hence, it is possible to simplify the process for manufacturing the semiconductor device of the modification 3.

In the semiconductor device of the modification 3, in erasing data in the memory cell MC, the sequencer 360 (see FIG. 1) applies a high voltage to one transistor TRs via the contact CGd connected to the transistor TRs, whereas in reading data from the memory cell MC, the sequencer 360 applies a low voltage to the other transistor TRs via the contact CGc connected to the other transistor TRs. Consequently, the bit line selection circuit BLSW can be formed using the transistors TRs having the same configuration.

In addition, the semiconductor device of the modification 3 can also obtain advantageous effects substantially similar to the advantageous effects of the above-described embodiment.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is

1. A semiconductor device comprising:
a first transistor including:
a first gate insulation layer,
a first gate electrode,
a second gate insulation layer, and
a second gate electrode, which are stacked in this order one upon the other;
a first contact connected to the first gate electrode; and
a second contact connected to the second gate electrode.

2. The semiconductor device according to claim 1, wherein the first gate electrode and the second gate electrode are electrically separated from each other by the second gate insulation layer.

3. The semiconductor device according to claim 1, further comprising:
a first memory cell; and
a first word line connected to the first memory cell, wherein
the first transistor further includes a source/drain region below the first gate insulation layer, and
the source/drain region is connected to the first word line.

4. The semiconductor device according to claim 3, further comprising:
a control circuit configured to control an operation of the first memory cell, wherein
the control circuit is configured to:
apply a first voltage to the first transistor via the second contact when data is written into the first memory cell, and
apply a second voltage to the first transistor via the first contact when data is read from the first memory cell, the second voltage being lower than the first voltage.

5. The semiconductor device according to claim 3, further comprising:
a second transistor spaced from the first transistor in a first direction, the second transistor including:
a third gate insulation layer,
a third gate electrode,
a fourth gate insulation layer, and
a fourth gate electrode being stacked in this order one upon the other, wherein
the second transistor shares the source/drain region with the first transistor.

6. The semiconductor device according to claim 5, further comprising:
a second memory cell; and
a second word line connected to the second memory cell, wherein
the source/drain region is connected to the second word line.

7. The semiconductor device according to claim 1, further comprising:
a memory cell; and
a bit line connected to the memory cell, wherein
the first transistor further includes a source/drain region below the first gate insulation layer, and
the source/drain region is connected to the bit line.

8. The semiconductor device according to claim 1, further comprising:
a third transistor that shares the first gate electrode with the first transistor, wherein
the first transistor further includes a first source/drain region below the first gate insulation layer,
the third transistor includes:
a third gate insulation layer below the first gate electrode, and
a second source/drain region below the third gate insulation layer, wherein
the first and second source/drain regions are electrically separated from each other.

9. The semiconductor device according to claim 8, wherein
the third transistor further includes:
a third gate electrode above the first gate electrode shared by the third transistor and the first transistor, and
the third gate electrode is separated from the second gate electrode.

10. The semiconductor device according to claim 8, wherein the third transistor shares the second gate electrode with the first transistor.

11. A semiconductor device, comprising:
a plurality of source/drain regions in a semiconductor layer, the source drain regions extending in a first direction parallel to the semiconductor layer and spaced from each other in a second direction intersecting the first direction and parallel to the semiconductor layer;
a first transistor including:
a first gate insulation layer,
a first gate electrode,
a second gate insulation layer, and
a second gate electrode, which are stacked in this order one upon the other in a third direction orthogonal to the semiconductor layer;
a first contact connected to an upper surface of the first gate electrode; and
a second contact connected to an upper surface of the second gate electrode.

12. The semiconductor device according to claim 11, wherein the first gate electrode and the second gate electrode are electrically separated from each other by the second gate insulation layer.

13. The semiconductor device according to claim 11, further comprising:
a first memory cell; and
a first word line connected to the first memory cell, wherein
a source/drain region of the plurality of source/drain regions is below the first gate insulation layer, and
the source/drain region is connected to the first word line.

14. The semiconductor device according to claim 13, further comprising:
a control circuit configured to control an operation of the first memory cell, wherein
the control circuit is configured to:
apply a first voltage to the first transistor via the second contact when data is written into the first memory cell, and
apply a second voltage to the first transistor via the first contact when data is read from the first memory cell, the second voltage being lower than the first voltage.

15. The semiconductor device according to claim 13, further comprising:
a second transistor spaced from the first transistor in the first direction, the second transistor including:
a third gate insulation layer,
a third gate electrode,
a fourth gate insulation layer, and
a fourth gate electrode being stacked in this order one upon the other in the third direction, wherein
the second transistor shares the source/drain region with the first transistor.

16. The semiconductor device according to claim 15, further comprising:
a second memory cell; and
a second word line connected to the second memory cell, wherein
the source/drain region is connected to the second word line.

17. The semiconductor device according to claim 11, further comprising:
a memory cell; and
a bit line connected to the memory cell, wherein
a source/drain region of the plurality of the source/drain regions is below the first gate insulation layer, and
the source/drain region is connected to the bit line.

18. The semiconductor device according to claim 11, further comprising:
a third transistor that shares the first gate electrode with the first transistor, wherein
a first source/drain region of the plurality of source/drain regions is below the first gate insulation layer,
the third transistor includes:
a third gate insulation layer below the first gate electrode, and
a second source/drain region of the plurality of source/drain regions is below the third gate insulation layer, wherein
the first and second source/drain regions are electrically separated from each other by an isolation structure.

19. The semiconductor device according to claim 18, wherein
the third transistor further includes:
a third gate electrode above the first gate electrode shared by the third transistor and the first transistor, and
the third gate electrode is separated from the second gate electrode.

20. The semiconductor device according to claim 18, wherein the third transistor shares the second gate electrode with the first transistor.
